(19) United States
(12) Patent Application Publication
(10) Pub. No.: US 2007/0096261 A1
(43) Pub. Date: May 3, 2007

(54) Semiconductor device and manufacturing method thereof

(76) Inventors: Seiji Otake, Saitama (JP); Ryo Kanda, Gunma (JP); Shuichi Kikuchi, Gunma (JP)

Correspondence Address: FISH & RICHARDSON P.C., P.O. BOX 1022, MINNEAPOLIS, MN, 55440-1022, US

(21) Appl. No.: 11/512,617

(22) Filed: Aug. 29, 2006

(30) Foreign Application Priority Data
Sep. 27, 2005 (JP) 2005-280518

(51) Int. Cl. H01L 29/861; H01L 31/107

(52) U.S. Cl. 257/603

(57) ABSTRACT

In a conventional semiconductor device, there is a problem that zener diode characteristics vary due to a crystal defect on a silicon surface, and the like. In a semiconductor device of the present invention, an N type epitaxial layer 4 is formed on a P type single crystal silicon substrate 2. In the epitaxial layer 4, P type diffusion layers 5, 6, 7 and 8 as anode regions and an N type diffusion layer 9 as a cathode region are formed. A PN junction region between the P type diffusion layer 8 and the N type diffusion layer 9 forms a zener diode 1. By use of this structure, a current path is located in a deep portion of the epitaxial layer 4. Thus, it is made possible to prevent a variation in a saturation voltage of the zener diode 1 due to a crystal defect on a surface of the epitaxial layer 4, and the like.

### BACKGROUND OF THE INVENTION

Priority is claimed to Japanese Patent Application Number JP2005-280518 filed on Sep. 27, 2005, the disclosure of which is incorporated herein by reference in its entirety.

1. Field of the Invention

The present invention relates to a semiconductor device which improves zener diode characteristics, and a manufacturing method thereof.

2. Description of the Related Art

In a conventional semiconductor device, for example, a zener diode, a P type region is formed in a lower part of a silicon substrate. On the P type region, an N type buried diffusion layer is selectively formed. On the N type buried diffusion layer, an N type epitaxial layer is formed. In the N type epitaxial layer, a P type diffusion layer and an N type diffusion layer are formed so as to be adjacent to each other. Moreover, with the P type diffusion layer and the N type diffusion layer, a PN junction region of the zener diode is formed. This technology is described for instance in Japanese Patent Application Publication No. 2005-197357, pp. 7 and 8, and FIGS. 3.

As described above, in the conventional semiconductor device, the P type diffusion layer and the N type diffusion layer are formed in the N type epitaxial layer. Thus, the PN junction region of the zener diode is formed. Moreover, in the P type diffusion layer and the N type diffusion layer, high-concentration impurity regions are formed on surfaces thereof and in region adjacent thereto. By this structure, a surface of the epitaxial layer and the PN junction region adjacent thereto are mainly used as operation regions. Thus, the device is easily affected by crystallizability of the surface of the epitaxial layer. For example, by a step of implanting impurities into the epitaxial layer by ion implantation, a crystal defect is generated on the surface of the epitaxial layer. As a result, there is a problem that current characteristics of the zener diode vary and a saturation voltage also varies depending on a crystalline state of the surface of the epitaxial layer.

Moreover, in a method for manufacturing the conventional semiconductor device, after the N type epitaxial layer is formed on the silicon substrate, the P type diffusion layer and the N type diffusion layer are formed in the epitaxial layer. In this event, the P type diffusion layer and the N type diffusion layer are formed by ion implantation from the surface of the epitaxial layer, respectively. In this manufacturing method, it is required to take account of mask misalignment at the time of formation of the P type diffusion layer and the N type diffusion layer. Thus, there is a problem that it is difficult to reduce a device size.

### SUMMARY OF THE INVENTION

The present invention was made in consideration for the foregoing problems. A semiconductor device of the present invention includes a semiconductor layer, an anode diffusion layer and a cathode diffusion layer, which are formed in the semiconductor layer, an insulating layer formed on the semiconductor layer, and a contact hole formed in the insulating layer. In the semiconductor device, the anode diffusion layer has a high-concentration impurity region in a concave region in a bottom of the cathode diffusion layer and in a region adjacent thereto. Therefore, in the present invention, a zener diode is formed, in which a PN junction region in the bottom of a cathode region is used as an operation region. Thus, it is made possible to improve a current capacity and to suppress a variation in a saturation voltage.

Moreover, in the semiconductor device of the present invention, the concave region of the cathode diffusion layer is formed at least in an entire opening region of the contact hole. Therefore, in the present invention, the PN junction region to be a main operation region is formed so as to correspond to a shape of the opening of the contact hole. Thus, a device size can be reduced.

Furthermore, in the semiconductor device of the present invention, a PN junction region formed in the concave region is formed in a region more than 1 μm deeper than a surface of the semiconductor layer. Therefore, in the present invention, by forming the PN junction region to be the main operation region in the semiconductor layer, an influence of a crystal defect formed on the surface of the semiconductor layer and in a region adjacent thereto can be avoided.

Moreover, a method for manufacturing the semiconductor device according to the present invention includes the steps of forming the anode diffusion layer in the semiconductor layer and forming the cathode diffusion layer so as to overlap with a part of the anode diffusion layer, forming the insulating layer on the semiconductor layer, forming the contact hole in the insulating layer, and forming a resist mask on the insulating layer so as to cause the contact hole on the cathode diffusion layer to have an opening, and performing ion implantation into the cathode diffusion layer through the opening of the contact hole, and forming a high-concentration impurity region of the anode diffusion layer in the bottom of the cathode diffusion layer and in the region adjacent thereto. Therefore, in the present invention, by forming the high-concentration impurity region of the anode diffusion layer in the bottom of the cathode diffusion layer through the contact hole, an amount of mask misalignment is reduced. Thus, the device size can be reduced.

In addition, in the method for manufacturing the semiconductor device according to the present invention, in the step of forming the high-concentration impurity region, impurities are implanted by ion implantation at an acceleration voltage that penetrates the cathode diffusion layer. Therefore, in the present invention, by forming the high-concentration impurity region of the anode diffusion layer through the contact hole, it is made possible to improve the current capacity of the zener diode and to suppress the variation in the saturation voltage.

In the present invention, the high-concentration impurity region of a P type diffusion layer used as an anode region is formed in the bottom of an N type diffusion layer used as the cathode region and in the region adjacent thereto. By use of this structure, the main operation region of the zener diode is located in a deep portion of an epitaxial layer. Thus, it is made possible to improve the current capacity and to suppress the variation in the saturation voltage.

Moreover, in the present invention, the high-concentration impurity region of the P type diffusion layer used as the anode region is formed so as to correspond to the shape of the opening of the contact hole on the cathode region. By use of this structure, the high-concentration impurity region can be formed with high positional accuracy, and the device size can be reduced.

Furthermore, in the present invention, after the cathode region is formed, the high-concentration impurity region of the P type diffusion layer used as the anode region is formed through the contact hole on the cathode region. By use of this manufacturing method, the high-concentration impurity region of the P type diffusion layer can be formed with high positional accuracy, and the device size can be reduced.

Moreover, in the present invention, impurities are implanted by ion implantation under the condition that the high-concentration impurity region of the P type diffusion layer is formed in the bottom of the cathode region and in the region adjacent thereto. By use of this manufacturing method, the main operation region of the zener diode is located in the deep portion of the epitaxial layer. Thus, it is made possible to improve the current capacity and to suppress the variation in the saturation voltage.

### BRIEF DESCRIPTION OF THE DRAWINGS

FIGS. 1A and 1B are cross-sectional views showing a semiconductor device according to an embodiment of the present invention.

FIG. 2 is a cross-sectional view showing a method for manufacturing the semiconductor device according to the embodiment of the present invention.

FIG. 3 is a cross-sectional view showing the method for manufacturing the semiconductor device according to the embodiment of the present invention.

FIG. 4 is a cross-sectional view showing the method for manufacturing the semiconductor device according to the embodiment of the present invention.

FIG. 5 is a cross-sectional view showing the method for manufacturing the semiconductor device according to the embodiment of the present invention.

FIG. 6 is a cross-sectional view showing the method for manufacturing the semiconductor device according to the embodiment of the present invention.

FIG. 7 is a cross-sectional view showing the method for manufacturing the semiconductor device according to the embodiment of the present invention.

### DESCRIPTION OF THE EMBODIMENTS

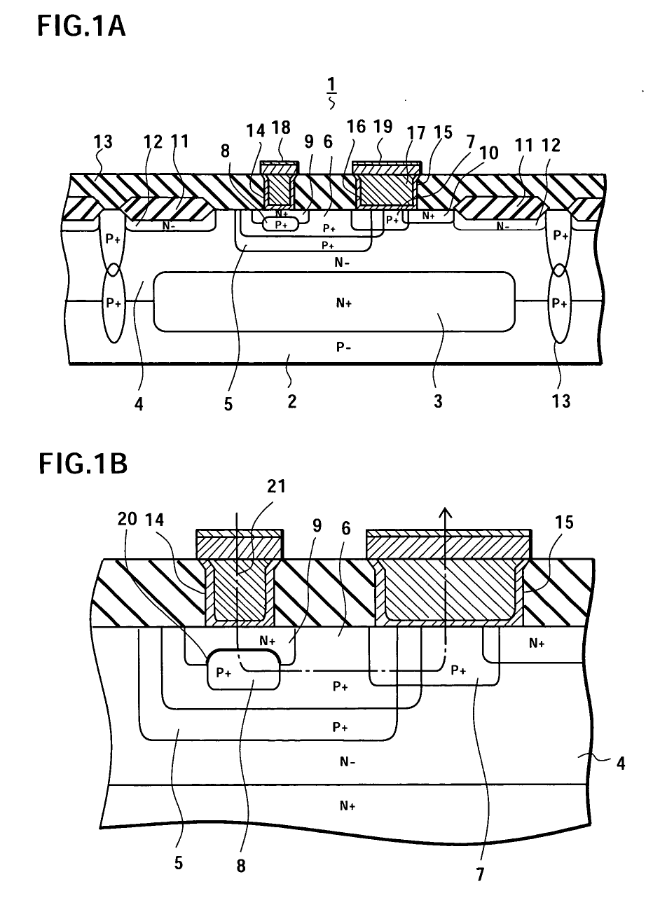

With reference to FIGS. 1A and 1B, a semiconductor device according to an embodiment of the present invention will be described in detail below. FIGS. 1A and 1B are cross-sectional views showing the semiconductor device of this embodiment.

As shown in FIG. 1A, a zener diode 1 mainly includes a P type single crystal silicon substrate 2, an N type buried diffusion layer 3, an N type epitaxial layer 4, P type diffusion layers 5, 6, 7 and 8 used as anode regions, an N type diffusion layer 9 used as a cathode region, and an N type diffusion layer 10.

The N type epitaxial layer 4 is formed on the P type single crystal silicon substrate 2. In the substrate 2 and the epitaxial layer 4, the N type buried diffusion layer 3 is formed. Note that each of the substrate 2 and the epitaxial layer 4 in this embodiment corresponds to a “semiconductor layer” of the present invention. Although the case where one epitaxial layer 4 is formed on the substrate 2 is described in this embodiment, the present invention is not limited thereto. For example, as the “semiconductor layer” of the embodiment of the present invention, only a substrate may be used or a plurality of epitaxial layers may be laminated on the substrate. Moreover, the substrate may be an N type single crystal silicon substrate or a compound semiconductor substrate.

The P type diffusion layers 5, 6, 7 and 8 are formed in the epitaxial layer 4 and used as the anode regions. The P type diffusion layers 5, 6 and 7 are disposed so as to partially overlap with each other in a transverse direction. Thus, a resistance value in the anode regions is reduced. Moreover, the P type diffusion layer 8 is formed in a region where the P type diffusion layers 5 and 6 overlap, and forms a high-concentration impurity region.

The N type diffusion layer 9 is formed in the region where the P type diffusion layers 5 and 6 overlap, and is used as the cathode region. The N type diffusion layer 9 uses its bottom region to form a PN junction region with the P type diffusion layer 8.

The N type diffusion layer 10 is formed in the epitaxial layer 4. The N type diffusion layer 10 is electrically connected to an anode electrode 19 and is set to have the same potential as that of the P type diffusion layer 7. Thus, prevention of an operation of a parasitic PNP transistor is realized.

A LOCOS (Local Oxidation of Silicon) oxide film 11 is formed in the epitaxial layer 4. A flat portion of the LOCOS oxide film 11 has a thickness of, for example, about 3000 to 5000 Å. Below the LOCOS oxide film 11, an N type diffusion layer 12 is formed. The N type diffusion layer 12 prevents inversion of a surface of the epitaxial layer 4.

An insulating layer 13 is formed on the epitaxial layer 4. The insulating layer 13 is formed of a BPSG (Boron Phospho Silicate Glass) film, a SOG (Spin On Glass) film or the like. By use of a heretofore known photolithography technology, contact holes 14 and 15 are formed in the insulating layer 13, for example, by dry etching using CHF₃+O₂ gas.

In the contact holes 14 and 15, barrier metal films 16 and tungsten (W) films 17 are buried. On surfaces of the tungsten films 17, aluminum-silicon-copper (Al—Si—Cu) films and barrier metal films are selectively formed. Moreover, a cathode electrode 18 and the anode electrode 19 are formed thereon.

As shown in FIG. 1B, in the zener diode 1, the P type diffusion layers 5, 6, 7 and 8 are set to be the anode regions, and the N type diffusion layer 9 is set to be the cathode region. Described in detail later in description for a method of manufacturing the semiconductor device, the P type diffusion layer 8 is formed by ion implantation through the contact hole 14 after the contact hole 14 is formed. By use of this manufacturing method, the P type diffusion layer 8 is formed below the N type diffusion layer 9 so as to correspond to a shape of an opening of the contact hole 14. Moreover, bulging of the P type diffusion layer 8 corresponding to the shape of the opening of the contact hole 14 forms a concave shape of the N type diffusion layer 9.

Specifically, as indicated by a thick solid line 20, the PN junction region between the P type diffusion layer 8 and the N type diffusion layer 9 is formed by utilizing a concave region. Moreover, the PN junction region is formed in a region more than at least about 1 μm deeper than the surface of the epitaxial layer 4. As described above, the region where the P type diffusion layer 8 is formed is set to be the high-concentration impurity region since the formation region thereof overlaps with those of the P type diffusion layers 5 and 6. By use of this structure, a main operation region of the zener diode 1 is set to be the PN junction region indicated by the thick line 20. Moreover, as indicated by a dashed line 21, by allowing a current to pass through a deep portion of the epitaxial layer 4 having good crystallizability, a variation in a saturation voltage in the zener diode 1 can be suppressed.

Furthermore, the bottom of the N type diffusion layer 9 is set to be the concave region so as to correspond to the shape of the opening of the contact hole 14. Thus, the PN junction region is expanded and the operation region can be expanded. By use of this structure, a current capacity of the zener diode 1 is improved, and zener diode characteristics can be improved.

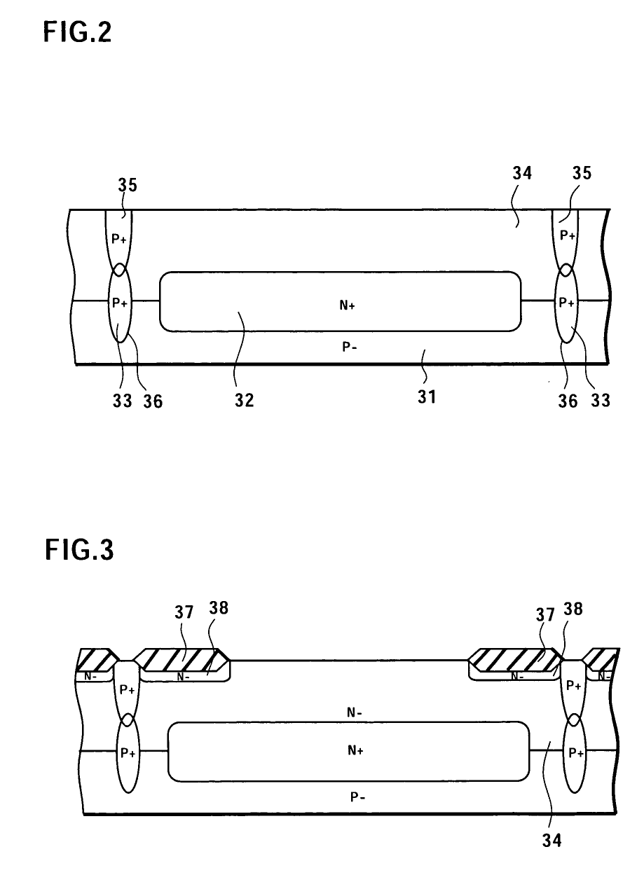

Next, with reference to FIGS. 2 to 7, detailed description will be given for a method of manufacturing a semiconductor device according to an embodiment of the present invention. FIGS. 2 to 7 are cross-sectional views showing the method of manufacturing the semiconductor device according to this embodiment.

First, as shown in FIG. 2, a P type single crystal silicon substrate 31 is prepared. Thereafter, by use of the heretofore known photolithography technology, N type impurities, for example, phosphorus (P) is implanted by ion implantation from a surface of the substrate 31 to form an N type buried diffusion layer 32. Next, by use of the heretofore known photolithography technology, P type impurities, for example, boron (B) is implanted by ion implantation from the surface of the substrate 31 to form a P type buried diffusion layer 33. Thereafter, the substrate 31 is placed on a susceptor of an epitaxial growth apparatus. Subsequently, a high temperature of about 1200° C., for example, is applied to the substrate 31 by lamp heating and, at the same time, SiHCl₃ gas and H₂ gas are introduced into a reaction tube. By this step, an epitaxial layer 34 having a specific resistance of 0.1 to 2.0 Ω·cm and a thickness of about 1.0 to 10.0 μm, for example, is grown on the substrate 31.

Thereafter, by use of the heretofore known photolithography technology, P type impurities, for example, boron (B) is implanted by ion implantation from a surface of the epitaxial layer 34 to form a P type diffusion layer 35. When the P type buried diffusion layer 33 and the P type diffusion layer 35 are connected to each other, an isolation region 36 is formed. As described above, the substrate 31 and the epitaxial layer 34 are separated into a plurality of island regions by the isolation regions 36.

Note that each of the substrate 31 and the epitaxial layer 34 in this embodiment corresponds to the “semiconductor layer” of the present invention. Although the case where one epitaxial layer 34 is formed on the substrate 31 is described in this embodiment, the present invention is not limited thereto. For example, as the “semiconductor layer” of the embodiment of the present invention, only the substrate may be used or the plurality of epitaxial layers may be laminated on the substrate. Moreover, the substrate may be the N type single crystal silicon substrate or the compound semiconductor substrate.

Next, as shown in FIG. 3, by use of an insulating layer having an opening provided in a portion where a LOCOS oxide film 37 is formed, as a mask, N type impurities, for example, phosphorus (P) is implanted by ion implantation to form an N type diffusion layer 38. Thereafter, by forming the LOCOS oxide film 37, the N type diffusion layer 38 can be formed with high positional accuracy with respect to the LOCOS oxide film 37.

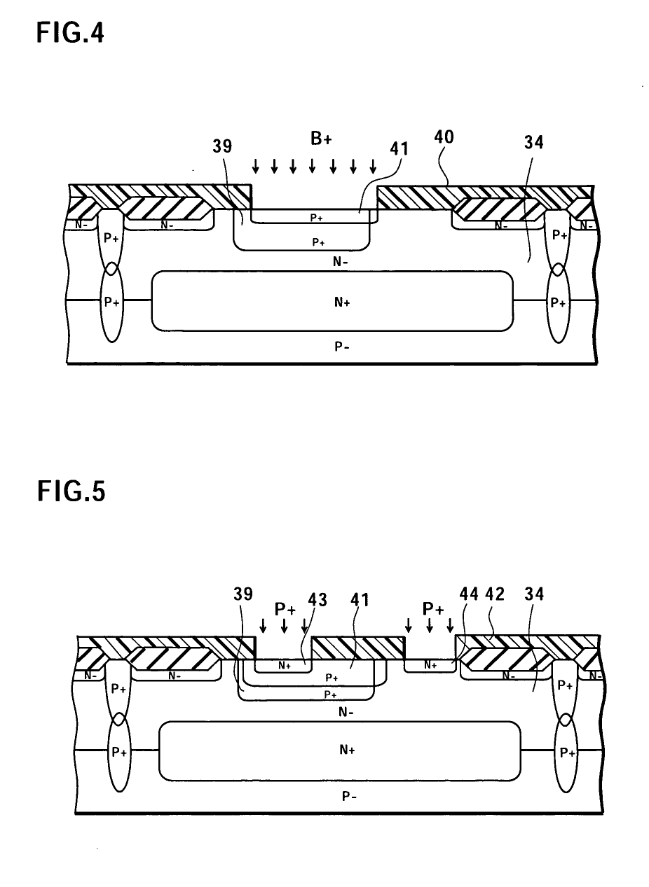

Next, as shown in FIG. 4, by use of the heretofore known photolithography technology, P type impurities, for example, boron (B) is implanted by ion implantation from the surface of the epitaxial layer 34 to form a P type diffusion layer 39. Thereafter, a photoresist 40 is formed on the epitaxial layer 34. Subsequently, by use of the heretofore known photolithography technology, an opening is formed in the photoresist 40 on a region where a P type diffusion layer 41 is to be formed. Thereafter, P type impurities, for example, boron (B) is implanted by ion implantation to form the P type diffusion layer 41.

Next, as shown in FIG. 5, a photoresist 42 is formed on the epitaxial layer 34. Thereafter, by use of the heretofore known photolithography technology, N type impurities, for example, phosphorus (P) is implanted by ion implantation to form N type diffusion layers 43 and 44. The N type diffusion layer 43 is formed so as to overlap with the P type diffusion layers 39 and 41. A region where the N type diffusion layer 43 and the P type diffusion layers 39 and 41 overlap with one another becomes an N type diffusion region, in which an N type impurity concentration and a P type impurity concentration offset each other.

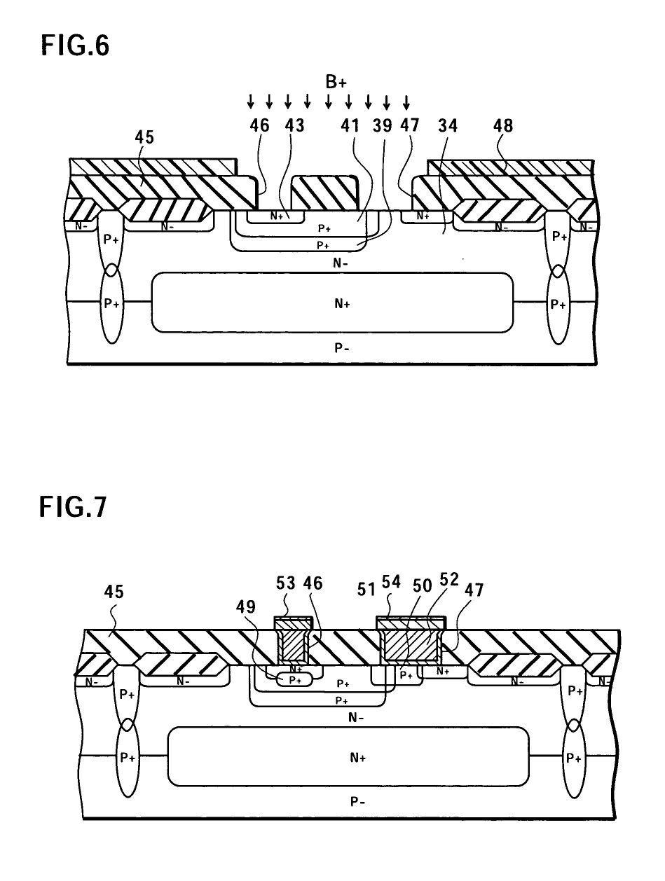

Next, as shown in FIG. 6, on the epitaxial layer 34, the BPSG film, the SOG film or the like, for example, is deposited as an insulating layer 45. Thereafter, by use of the heretofore known photolithography technology, contact holes 46 and 47 are formed in the insulating layer 45, for example, by dry etching using CHF₃+O₂ gas.

Thereafter, a photoresist 48 is formed on the insulating layer 45, and the photoresist 48 is selectively removed so as to provide openings of the contact holes 46 and 47 therein. Subsequently, through the contact holes 46 and 47, P type impurities, for example, boron (B) is implanted by ion implantation into the epitaxial layer 34 to form P type diffusion layers 49 and 50 (see FIG. 7). In this event, the ion implantation of boron (B) is performed under conditions of, for example, an acceleration voltage of 70 to 90 keV and a dose of 1.0×10³ to 1.0×10¹⁵/cm². By use of this manufacturing method, boron (B) is injected into a deep portion of the epitaxial layer 34, and the P type diffusion layer 49 (see FIG. 7) is formed into a shape of the opening of the contact hole 46 below the N type diffusion layer 43. Moreover, the PN junction region formed by the N type diffusion layer 43 and the P type diffusion layer 49 is formed in a region more than at least about 1 μm deeper than the surface of the epitaxial layer 34. Note that, by heat treatment in other steps after the ion implantation step of forming the P type diffusion layer 49, the P type diffusion layer 49 is somewhat laterally diffused from the shape of the opening of the contact hole 46. Moreover, in the bottom of the N type diffusion layer 43, bulging of the P type diffusion layer 49 forms the concave region so as to correspond to the shape of the contact hole 46.

Furthermore, in the ion implantation step of forming the P type diffusion layers 49 and 50, the contact holes 46 and 47 are utilized. Thus, it is not required to take account of mask misalignment between the P type diffusion layers 49 and 50, and the contact holes 46 and 47. For example, in the case where the contact holes 46 and 47 are formed after the P type diffusion layers 49 and 50 are formed, a mask misalignment width of about 0.6 (μm) is required around each of the contact holes 46 and 47, in addition to the widths of the contact holes 46 and 47. However, in this embodiment, it is not required to take account of the mask misalignment width. In the cross section shown in FIG. 7, mask misalignment widths (about 1.2 μm) which are considered to be on the left and right of the contact holes 46 and 47 can be omitted. Accordingly, a zener diode size can be reduced.

Lastly, as shown in FIG. 7, barrier metal films 51 are formed on inner walls of the contact holes 46 and 47, and the like. Thereafter, tungsten (W) films 52 are buried in the contact holes 46 and 47. On surfaces of the tungsten films 52, the aluminum-silicon-copper (Al—Si—Cu) films and the barrier metal films are deposited by use of a sputtering method. Thereafter, by use of the heretofore known photolithography technology, the aluminum-silicon-copper films and the barrier metal films are selectively removed to form a cathode electrode 53 and an anode electrode 54.

Note that, in this embodiment, the description has been given for the case where the P type diffusion layer 49 is formed by utilizing the contact hole 46 after the contact hole 46 is formed. However, the embodiment of the present invention is not limited to the case described above. For example, the following case may be adopted. Specifically, the P type diffusion layers 39 and 41 are formed, and the contact hole 46 is formed after the P type diffusion layer 49 is formed by using a photoresist as the mask. Also in this case, by setting the same ion implantation conditions, the P type diffusion layer 49 can be formed in a desired region. Accordingly, the current capacity of the zener diode can be improved. Besides the above, various changes can be made without departing from the scope of the embodiment of the present invention.

What is claimed is:

1. A semiconductor device comprising:
a semiconductor layer;
an anode diffusion layer and a cathode diffusion layer, which are formed in the semiconductor layer;
an insulating layer formed on the semiconductor layer; and
a contact hole formed in the insulating layer,
wherein the anode diffusion layer has a high-concentration impurity region in a concave region in a bottom of the cathode diffusion layer and in a region adjacent thereto.

2. The semiconductor device according to claim 1, wherein the concave region of the cathode diffusion layer is formed at least in an entire opening region of the contact hole.

3. The semiconductor device according to claim 1, wherein a PN junction region formed in the concave region is formed in a region more than 1 μm deeper than a surface of the semiconductor layer.

4. A method for manufacturing a semiconductor device, comprising the steps of:
forming an anode diffusion layer in a semiconductor layer and forming a cathode diffusion layer so as to overlap with a part of the anode diffusion layer;
forming an insulating layer on the semiconductor layer, forming a contact hole in the insulating layer, and therefore forming a resist mask on the insulating layer so as to cause the contact hole on the cathode diffusion layer to have an opening; and
performing ion implantation into the cathode diffusion layer through the opening of the contact hole, and forming a high-concentration impurity region of the anode diffusion layer in a bottom of the cathode diffusion layer and in a region adjacent thereto.

5. The method for manufacturing the semiconductor device, according to claim 4, wherein, in the step of forming the high-concentration impurity region, impurities are implanted by ion implantation at an acceleration voltage that penetrates the cathode diffusion layer.
